(19) United States
(12) Patent Application Publication
(10) Pub. No.: US 2010/0211830 A1
(43) Pub. Date: Aug. 19, 2010

(54) Multi-input multi-output read-channel architecture for recording systems

(75) Inventors: Sundararajan Sankaranarayanan, Wexford, PA (US); Raman Venkataramani, Pittsburgh, PA (US)

Correspondence Address: SEAGATE TECHNOLOGY LLC;C/O WESTMAN, CHAMPLIN & KELLY, P.A., SUITE 1400, 900 SECOND AVENUE SOUTH, MINNEAPOLIS, MN, 55402-3244, US

(73) Assignee: Seagate Technology LLC, Scotts Valley, CA (US)

(21) Appl. No.: 12/371,265

(22) Filed: Feb. 13, 2009

(51) Int. Cl. G06F 11/00; H03H 7/30; G06F 12/00

(52) U.S. Cl. 714/55; 375/232; 711/154; 714/E11.003

(57) ABSTRACT

In a particular embodiment, a storage device includes a data storage medium and a read/write circuit coupled the data storage medium via a communication channel. The read/write circuit includes a formatter circuit to receive a read back signal related to data stored on the data storage medium and to produce an output vector related to the read back signal. The read/write circuit further includes a multiple-input multiple-output (MIMO) equalizer coupled to the formatter circuit and adapted to generate an equalized output vector related to the output vector. The read/write circuit also includes a MIMO detector coupled to the MIMO equalizer and adapted to generate hard bit decisions based on the equalized output vector.

### FIELD

The present disclosure relates generally to a multiple-input multiple-output read-channel architecture for recording systems.

### BACKGROUND

In bit-patterned media, magnetic islands are staggered in two sub-tracks that constitute a single track for data storage. Along each sub-track, a magnetic island by a non-magnetic region called a trench. The dimension of the read-head in a down-track direction can be large enough to cover the entire track. In such an arrangement, a read-back signal can include two convolution terms (in the absence of jitter), and two dot-responses, one for each sub-track, is used to determine a clean version of the read-back signal.

### SUMMARY

In a particular embodiment, a storage device includes a data storage medium and a read/write circuit coupled the data storage medium via a communication channel. The read/write circuit includes a formatter circuit to receive a read back signal related to data stored on the data storage medium and to produce an output vector related to the read back signal. The read/write circuit further includes a multiple-input multiple-output (MIMO) equalizer coupled to the formatter circuit and adapted to generate an equalized output vector related to the output vector. The read/write circuit also includes a MIMO detector coupled to the MIMO equalizer and adapted to generate hard bit decisions based on the equalized output vector.

In another particular embodiment, a system is disclosed that includes a multiple-input multiple-output (MIMO) equalizer adapted to receive an input vector related to a read-back signal from a data storage medium to produce an equalized output vector. The system further includes a MIMO detector adapted to decode the equalized output vector to generate hard bit decisions and to provide the hard bit decisions to an output.

In still another particular embodiment, a method is disclosed that includes receiving a vector bit stream related to a read back signal from a channel at a multiple-input multiple-output (MIMO) equalizer and generating an equalized output vector related to the vector bit stream via the MIMO equalizer. The method further includes generating hard bit decisions based on the equalized output vector using a MIMO detector and providing the hard bit decisions to an output.

### BRIEF DESCRIPTION OF THE DRAWINGS

FIG. 1 is a block diagram of a particular illustrative embodiment of a multiple-input multiple-output (MIMO) inter-symbol interference channel;

FIG. 2 is a block diagram of a particular illustrative embodiment of a MIMO target channel for the equalized target channel illustrated in FIG. 1;

FIG. 3 is a diagram of a particular illustrative embodiment of a multiple-input multiple-output (MIMO) read-channel architecture;

FIG. 4 is a block diagram of a second particular embodiment of a MIMO read-channel architecture;

FIG. 5 is a graph of bit error rate (BERs) versus signal-to-noise ratios (SNRs) for particular illustrative embodiments of single-input single-output (SISO) and MIMO Viterbi-based read-channel architectures with a read-head deviation of zero percent (0%), minus ten percent (−10%), and plus ten percent (+10%);

FIG. 6 is a graph of BER versus SNRs for the illustrative embodiments of the SISO and MIMO Viterbi-based read-channel architectures of FIG. 5 with size jitter at 5% and position jitter at 5%;

FIG. 7 is a graph of BERs versus SNRs for particular embodiments of a SISO Viterbi-based detector, a MIMO Viterbi-based detector, and a MIMO data-dependent noise-prediction detector with size jitter at 5% and position jitter at 20%;

FIG. 8 is a block diagram of a particular illustrative embodiment of a system including a hybrid storage device having a read channel that includes a MIMO equalizer, MIMO target filter, and a MIMO detector;

FIG. 9 is a flow diagram of a particular illustrative embodiment of a method of determining a read-back signal using a MIMO detector; and

FIG. 10 is a flow diagram of a second particular illustrative embodiment of a method of determining a read-back signal using a MIMO detector.

### DETAILED DESCRIPTION OF ILLUSTRATIVE EMBODIMENTS

In bit-patterned media (BPM), magnetic islands can be staggered in the two sub-tracks that constitute a single data recording track of the BPM. Along each sub-track, a magnetic island is followed by a non-magnetic region called the trench. The dimension of the read-head along the down-track direction can be large enough to cover the entire track. In this arrangement, it is observed that the read-back signal can be described as the sum of two convolution terms (in the absence of jitter). In other words, two dot responses (one for each sub-track) can be used to describe the clean-version of the read-back signal. The distinction between the two dot responses grows with an increase in the off-track head deviation. This distinction can be captured as an amplitude variation and/or a half-width variation. In single-input single-output systems, it may be assumed that the read back signal can be modeled as a convolution of user data and the channel response, which may not be true for BPM storage systems.

In a particular embodiment, a multiple-input multiple-output (MIMO) read-channel architecture is disclosed that includes a MIMO equalizer, a MIMO target filter, a MIMO data-dependent noise prediction (DDNP) detector to output symbol-level or bit-level reliabilities, and a modified timing recovery unit. It should be understood that the MIMO read-channel architecture can be used with bit-pattern media systems and as well as other types of data storage media, including, for example, perpendicular data recording media. The read-back signal from a BPM channel can be described according to the following equation:

$$\begin{matrix}y [ n ] = {\sum }_{k} {x}_{T} [ k ] {φ}_{T} [ n - k ] + {\sum }_{k} {x}_{B} [ k ] {φ}_{B} [ n - k ] \\ = {\sum }_{l} {x}_{T} [ 2 l + 1 ] {φ}_{T} [ n - 2 l - 1 ] + \\ {\sum }_{l} {x}_{B} [ 2 l + 2 ] {φ}_{B} [ n - 2 l - 2 ] \\ = {\sum }_{l} 〈 {φ}_{T} [ n - 2 l - 1 ] {φ}_{B} [ n - 2 l - 2 ] 〉 ( \begin{matrix}{X}_{T} [ 2 l + 1 ] \\ {X}_{B} [ 2 l + 2 ]\end{matrix} )\end{matrix} \qquad ( Equation 1 )$$

In Equation 1, the variables X_{T} and X_{B} represent user symbols corresponding to top and bottom sub-tracks of a bit pattern media (BPM). These symbol vectors are formed from the user symbol sequence x by dividing into two streams X_{T} and X_{B} such that X_{T}[2k]=0 and X_{B}[2k+1]=0 for ∀k. Additionally, the variables φ_{T} and φB represent responses corresponding to magnetic islands (or dots) in the top and bottom sub-track, respectively. In a particular embodiment, these responses can be very different from each other, depending on the off-track deviation of the read-head.

$$( \begin{matrix}y [ 2 n + 1 ] \\ y [ 2 n + 2 ]\end{matrix} ) = {\sum }_{l} ( \begin{matrix}{φ}_{T} [ 2 n + 1 - 2 l - 1 ] {φ}_{B} [ 2 n + 1 - 2 l - 2 ] \\ {φ}_{T} [ 2 n + 1 - 2 l - 1 ] {φ}_{B} [ 2 n + 2 - 2 l - 2 ]\end{matrix} ) ( \begin{matrix}{x}_{T} [ 2 l + 1 ] \\ {x}_{B} [ 2 l + 2 ]\end{matrix} ) \\ \\ ( \begin{matrix}y [ 2 n + 1 ] \\ y [ 2 n + 2 ]\end{matrix} ) = {\sum }_{l} ( \begin{matrix}even taps of {φ}_{T} & odd taps of {φ}_{B} \\ odd taps of {φ}_{T} & even taps of {φ}_{B}\end{matrix} ) ( \begin{matrix}x [ 2 l + 1 ] \\ x [ 2 l + 2 ]\end{matrix} ) \qquad ( Equation 2 )$$

An equivalent two-input and two-output channel can be defined according to the following equation:

$$( \begin{matrix}{y}_{T} \\ {y}_{B}\end{matrix} ) [ {n}^{′} ] = {\sum }_{k} ( \begin{matrix}{h}_{1 , 1} & {h}_{1 , 2} \\ {h}_{2 , 1} & {h}_{2 , 2}\end{matrix} ) [ {n}^{′} - {k}^{′} ] ( \begin{matrix}{x}_{T} \\ {x}_{B}\end{matrix} ) [ {k}^{′} ] \qquad ( Equation 3 )$$

The time index n′ represents samples at instances 2n and 2n+1, and the time index k′ represent samples at instances 2k and 2k+1. Also, x_{T}[k′] and x_{B}[k′] are bits x[2k+1] and x[2k+2], respectively. The channel model can be simply defined according to the following equation:

y:=H*x+w (Equation 4)

where the variable h is a 2×2 polynomial matrix representing the channel response, and the variable w represents the additive white noise random variable.

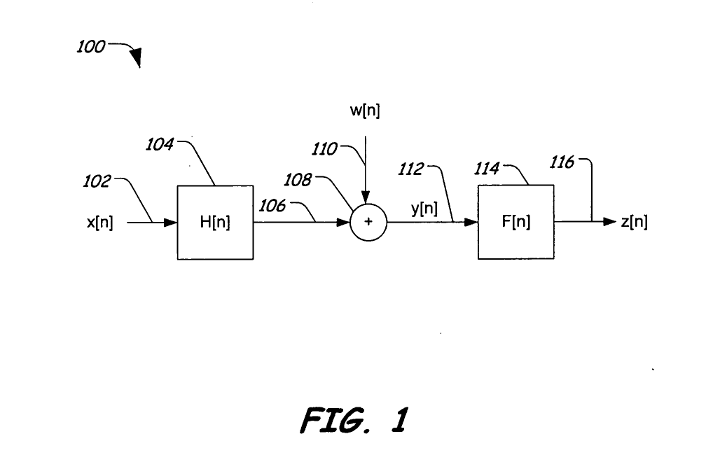

FIG. 1 is a block diagram of a particular embodiment of an equalized multiple-input multiple-output (MIMO) inter-symbol interference (ISI) channel 100. The inter-symbol interference channel 100 is adapted to receive sampled data (x[n]) 102 that are convolved with a channel response (H[n]) 104 to produce a channel output signal 106. The channel output signal 106 is corrupted by white noise (w[n]) 110 at node 108 to produce a corrupted signal (y[n]) 112. The corrupted signal (y[n]) 112 is passed through a multiple-input multiple-output (MIMO) equalizer (F[n]) 114 to generate an equalized output signal (z[n]) 116. The MIMO equalizer (F[n]) 114 is designed simultaneously with a generalized partial response (GPR) target filter.

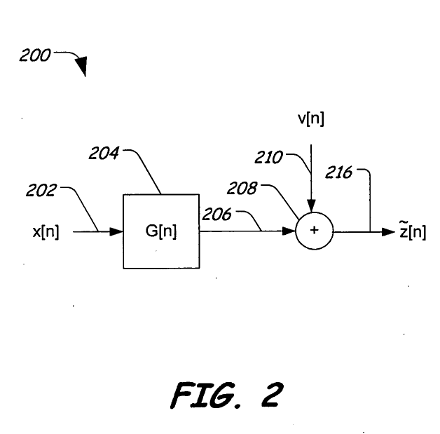

FIG. 2 is a block diagram of a particular embodiment of a multiple-input multiple-output (MIMO) target channel 200 for the equalized channel illustrated in FIG. 1. The target channel 200 is adapted to receive sampled data (x[n]) 202 (which can be the same sampled data (x[n]) 102 illustrated in FIG. 1) that are convolved with a target response (G[n]) via a target response filter 204 to produce a channel output signal 206. The channel output signal 206 is adjusted by a noise signal (v[n]) 210 at node 208 to produce a target output signal (\tilde{z}[n]) 216. In a particular example, the GPR target filter 204 and the MIMO equalizer filter (F[n]) 114 are designed to achieve a minimum mean squared error between the channel output signal 116 (in FIG. 1) and the target output signal 216 (in FIG. 2). In a particular example, the detector 100 is designed as if the data samples (x[n]) 102 (illustrated in FIG. 1) had passed through the target channel 200. In this example, the ISI channel 100 and the target channel 200 are assumed to be equivalent for detection purposes.

Using a minimum mean square error (MMSE) equalization error as a cost function, the variance of e:=G*x−F*y can be determined over all f and causal g subject to the monic determinant constraint:

det G[0]=1 [symbol] det G(z) is monic. (Equation 5)

The monic determinant constraint in Equation 5 is a natural constraint in an infinite impulse response (IIR) case because it manifests a posteriori equivalence of the equalized and target channel. In a particular embodiment, the generalized partial response equalizer and target illustrated in FIGS. 1 and 2 can be finite impulse response (FIR) filters according to the following equations:

F={F[k]:−K≦k≦K} (Equation 6)

G={G[k]:0≦k≦L} (Equation 7)

Considering the MMSE equalizer design for fixed target, the solution is obtained by solving for the related Toeplitz matrices. In particular, the solution is obtained by solving the following equation:

E(e[n]y*[n−1])=0 for −K≦1≦K (Equation 8)

which yields γR_{xy}=φR_{yy} where,

γ=(G[L],G[L−1], . . . , G[0]) (Equation 9)

φ=(F[K],F[K−1], . . . , F[−K]) (Equation 10)

and R_{xy} and R_{yy} are the related block Toeplitz matrices formed using the blocks r_{xy}[k] and r_{yy}[k], respectively. In a particular example, the second order statistics can be estimated by temporal averaging using a sufficiently long training data set because x and y are ergodic random processes. The solution is described by the following equation:

φ=γR_{xy}R_{yy}⁻¹ (Equation 11)

In this example, the minimum value for the equalization error variance can be determined according to the following equation:

ε=tr(γ(Rₓₓ−R_{xy}R_{yy}⁻¹R_{yx})γ*) (Equation 12)

Considering the target design problem, Equation 12 can be minimized over all causal targets g with lower-triangular function G[0] satisfying the determinant det G[0]=1. In a particular example, a minimized solution can be computed according to the following equation:

G*[0]γ/λ=(0, . . . , 0,I)(Rₓₓ−R_{xy}R_{yy}⁻¹R_{yx})⁻¹ (Equation 13)

In light of the Equations 1-13 above, a target read-back value can be determined according to the following equation:

d[k]:=G*[0]G[k]/λ (Equation 14)

To solve for g and d, the variable X can be selected to make the determinant det(λd[0])=1, and Equation 14 (for k=0) can be factored so that G[0] is lower-triangular. Then, Equation 15 below can be solved for the remaining terms:

G[k]=λ(G*[0])⁻¹d[k] (Equation 15)

In a printed bit patterned media (BPM), dot-size jitter and dot-position jitter introduce a pattern-dependency into the noise model. A data-dependent noise prediction (DDNP) detector can be used to correct for the pattern-dependent noise, particularly where the DDNP detector is adapted for a multiple-input multiple-output (MIMO) channel model of BPM systems.

For convenience, it is assumed that the number of sub-tracks (or sub-channels) of the BPM media can be represented as Nc=2. Additionally, a hard-decision Viterbi detector is assumed to be used. In this example, at any time instance k, the input bit b is a vector (Nc×1) that is passed through a MIMO channel and a MIMO equalizer. The MIMO equalizer and target filters, which have taps that are Nc×Nc matrices, can be designed to minimize the mean-squared error under a monic-determinant constraint. If the target filter G has an order (i.e., a number of taps) of I+1, then the matrices include an I+1×1 array of Nc×Nc matrices. For instance, G[0] is an Nc×Nc matrix having a unit determinant.

In a particular embodiment, the pattern-dependence in noise realizations can be dealt with by using a past L received noise samples and δ future bits. In this embodiment, a total number of states in a corresponding trellis is defined as (2^{Nc})^{L+I+δ} because L+I bits are required to recreate past L noise samples. There are 2^{Nc} branches that arrive and leave each state of the trellis, and therefore there are (2^{Nc})^{L+I+δ+1} branches in total. An array b_{k-L-I}^{k+δ} is an L+I+δ-array of 2×1 vectors, which array serves as a branch label for the branches of the trellis.

In a particular embodiment, a training stage includes determining a mean noise and prediction filters that are conditioned on the array b_{k-L-I}^{k+δ}. In a particular example, the mean noise n_{k-L}^{k} is conditioned on the array b_{k-L-I}^{k+δ}. The noise can be described according to the following equation:

n_{k-L}^{k}:=r_{k-L}^{k}−s_{k-L}^{k} (Equation 16)

where the variable r represents the equalizer output and the variable s represents an ideal (no noise) target output. The data-dependent noise prediction (DDNP) filters (q) can be conditioned on the array b_{k-L-I}^{k+δ}. For prediction purposes, the mean noise n_{k-L}^{k} is zeroed out by subtracting the estimated mean. In this example, a prediction filter is an L-array of 2×2 matrices that can be used to predict the pattern dependent component of the noise ñ, where the noise ñ represents a zero-mean component.

In the detection stage, for each branch of the trellis, a noise prediction for each sampled bit can be described by the following equation:

\hat{n}ₖ:=ñₖ−q*(ñ_{k-L}^{k}) (Equation 17)

Assuming that a hard-decision Viterbi algorithm is used for detection, the branch metric can be described according to the following equation:

$$\frac{{\hat{n}}_{k}^{′} {C}^{- 1} {\hat{n}}_{k}}{Nc} \qquad ( Equation 18 )$$

where the variable C represents the predictor error variance. The mean noise vectors for the mean noise n_{k-L}^{k} are estimated for each branch. The non-zero mean is a result of noise coloring at the output of the equalizer. Also, the predictor error variance of two 2×1 vectors is a 2×2 matrix.

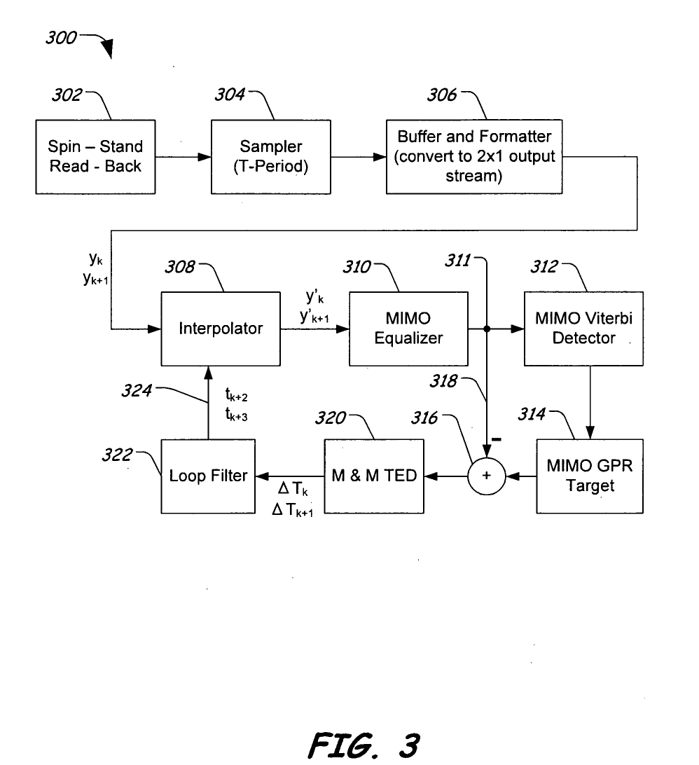

FIG. 3 is a diagram of a particular illustrative embodiment of a multiple-input multiple-output (MIMO) read-channel architecture 300. The architecture 300 includes data source 302 to provide a read back signal and a sampler 304 having a sample period (T) to sample the read-back signal. The sampler 304 provides the sampled read back data to a buffer and formatter 306, which is adapted to convert the sampled read back data to a 1×2 output stream (yₖ, yₖ₊₁). The sampled read back data is provided to an interpolator 308. At every 2T instance, the interpolator 308 also receives a timing feedback vector (a 1×2 vector (τₖ, τₖ₊₁)) via line 324 from a loop filter 322 and produces an interpolated vector (y_{kT}+τₖ, y_{(k+1)T}+τₖ+1) that is provided to a MIMO equalizer 310. The MIMO equalizer 310 provides an equalized output vector to a node 311 that is coupled to a MIMO Viterbi detector 312, which produces hard bit decisions (b_{k-δ}, b_{k+1-δ}) from the equalized output vector and provides the hard bit decisions to a MIMO generalized partial response (GPR) target filter 314, which produces a target output vector. The equalized output at the node 311 is subtracted from the target output vector of the MIMO GPR target filter 314 at 316 to produce timing error data that is provided to a timing error detector 320, which produces a 1×2 timing error vector (ΔTₖ, ΔTₖ₊₁). In a particular embodiment, the timing error detector 320 can be a Mueller-Müller (M&M) Timing error detector adapted to apply an M&M timing update rule, except that two timing updates at each 2T instance are generated by the timing error detector 320. The timing error vector (ΔTₖ, ΔTₖ₊₁) is provided to a loop filter 322, which generates a timing instance vector (tₖ₊₂, tₖ₊₃) that is fed back to the interpolator 308.

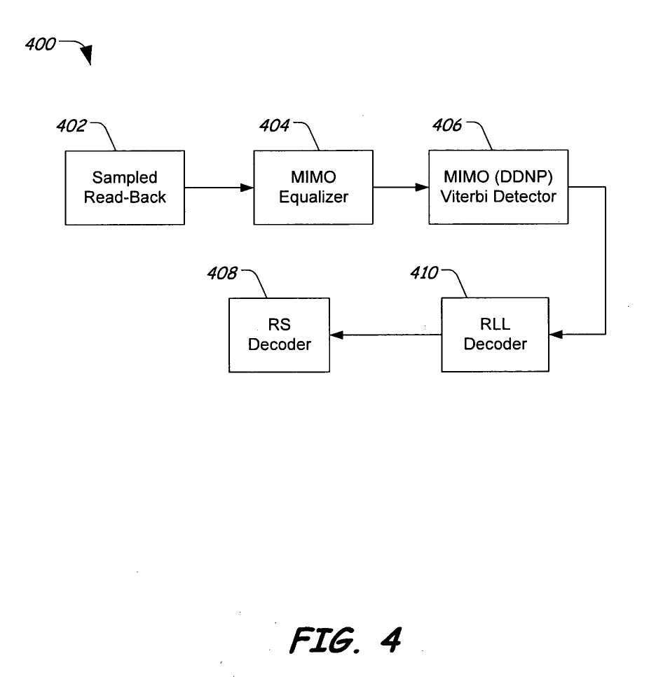

FIG. 4 is a block diagram of a second particular embodiment of a MIMO read-channel architecture 400. The architecture 400 is a non-iterative MIMO architecture. The architecture 400 includes a sampled read-back input 402 that is converted to a stream of 1×2 vectors that are provided to a multiple-input multiple-output (MIMO) equalizer 404, which is a two-input and two-output equalizer and which produces an equalized output that is a 1×2 vector. The equalized output is provided to a MIMO data-dependent noise predictive (DDNP) Viterbi detector 406. The detector 406 provides a vector of hard bit-decisions to a run length limited (RLL) decoder 410, which provides decoded data to a Reed-Solomon (RS) decoder 410 to produce the user data from the sampled read-back input 402.

In a particular example, a side-by-side comparison of a SISO architecture and a MIMO architecture 400 was made. In this example, the SISO architecture had an equalizer filter of length 31 and a generalized partial response (GPR) target filter of length 16. The MIMO architecture 400 had a MIMO equalizer filter of length 15 and a GPR target filter of length 3. For MIMO architecture 400 and SISO architecture, Viterbi and Viterbi data-dependent noise predictive (DDNP) detectors were used. For the MIMO architecture 400, MIMO detectors are used and, for the SISO architecture, SISO detectors are used. The lengths of the prediction filters of the MIMO architecture 400 and the SISO architecture are chosen such that they process the same number of read back data samples. The results of a side-by-side comparison are shown in TABLE 1 below.

TABLE 1
SISO versus MIMO on 600 Mbps Packets.

| Architecture | GPR Taps | Detector | Channel BER | CS |
|---|---|---|---|---|
| SISO | 6 | Viterbi | 4.06 × 10⁻⁴ | 0 |
| MIMO | 3 | Viterbi | 6.90 × 10⁻⁵ | 0 |
| SISO | 6 | Viterbi-DDNP | 3.49 × 10⁻⁴ | 0 |
| MIMO | 3 | Viterbi-DDNP | 1.07 × 10⁻⁴ | 0 |

The data in Table 1 was obtained by processing signal read back from perpendicular recording media. In this particular example, the read head does not span over multiple tracks. In other words, adjacent tracks were not read. In this particular example, the MIMO equalizer-target concept was applied to a channel with a single track, and the two input streams were generated by partitioning serial read back from the channel. In Table 1, two hundred fifty (250) sectors of a bit patterned media (BPM) were processed. The BER computation excludes the sectors used to train the prediction filters. The side-by-side test of Table 1 demonstrates that the MIMO architecture 400 outperforms the SISO architecture. In this particular instance, the MIMO architecture 400 with the Viterbi-DDNP detector did not gain over the MIMO architecture with the Viterbi detector (and without noise prediction). In this particular example, the discrepancy may be attributed to the length of the noise prediction training process.

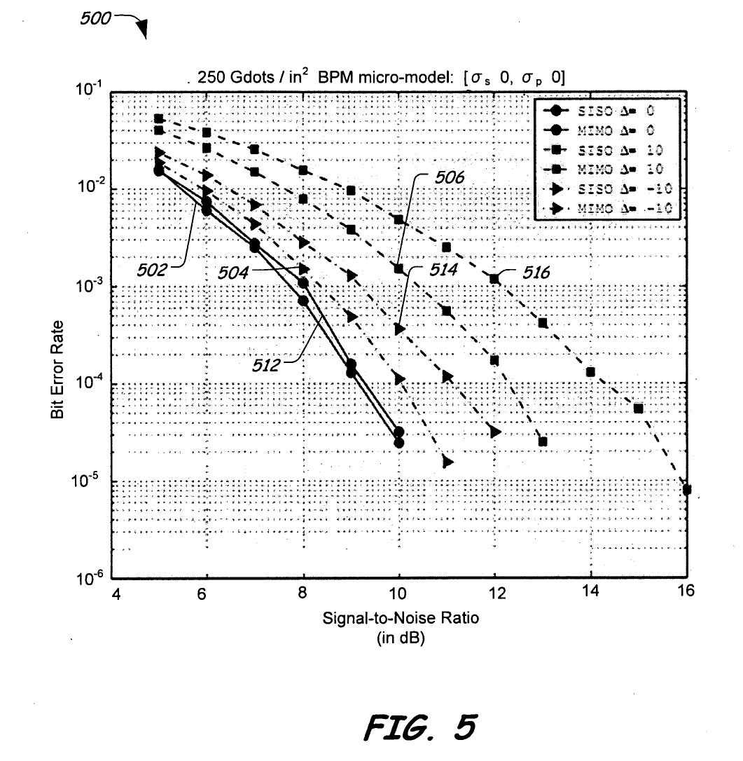

FIG. 5 is a graph 500 of bit error rates (BERs) versus signal-to-noise ratios (SNRs) for particular illustrative embodiments of single-input single-output (SISO) and MIMO Viterbi-based read-channel architectures with a read-head deviation of zero percent (0%), minus ten percent (−10%), and plus ten percent (+10%). In this instance, the equalizer and target filters are MIMO filters where each tap is a 2×2 matrix. In a particular embodiment, a monic determinant constraint is imposed. The MIMO equalizer receives a 2-bit input and produces a 2-bit output. For a BPM system that has a density of 250 Gdots/in² (Giga-Islands/in²), the equalizer lengths of the SISO and MIMO architectures were 31 and 15, respectively. Further, the target lengths of the SISO and MIMO architectures were 6 and 3, respectively. In the SISO and MIMO architectures, the same number of bits/received symbols were used in processing. Further, in this particular instance, the data-dependent noise prediction (DDNP) detector parameters include past sample bits (L) and future bits (δ). The SISO and MIMO architectures include 2 and 1 future bits, respectively, and includes 2 and 1 past bits, respectively.

The graph 500 includes a line 502 that represents BER versus SNR for a MIMO detector with an on-track read head (i.e., the read head position delta (A) is zero). The graph 500 further includes lines 504 and 506 that represent BER versus SNR for a MIMO detector where the read head is off-track by minus or plus ten percent (10%), respectively (i.e., the read head position delta is +10 or −10). The graph also includes lines 512, 514, and 516 representing a SISO detector with a read head that is on track (A=0) and off-track by minus or plus 10% (A=+10%), respectively.

In a particular example, for the SISO and MIMO detectors where the read head is on-track (i.e., at A=0), the dot responses (or BER versus SNR responses) are similar, and (as shown at 502 and 512) hence the MIMO detector does not produce an observable SNR gain. However, when the read head deviates from the track by ten percent (as indicated at 506), the MIMO detector produces a gain of about two (2) dB. When the read head deviates from the track by minus ten percent (as indicated at 504), the MIMO detector gain is approximately one (1) dB. The gains observed from the MIMO detector can be attributed to the MIMO equalizer and target design.

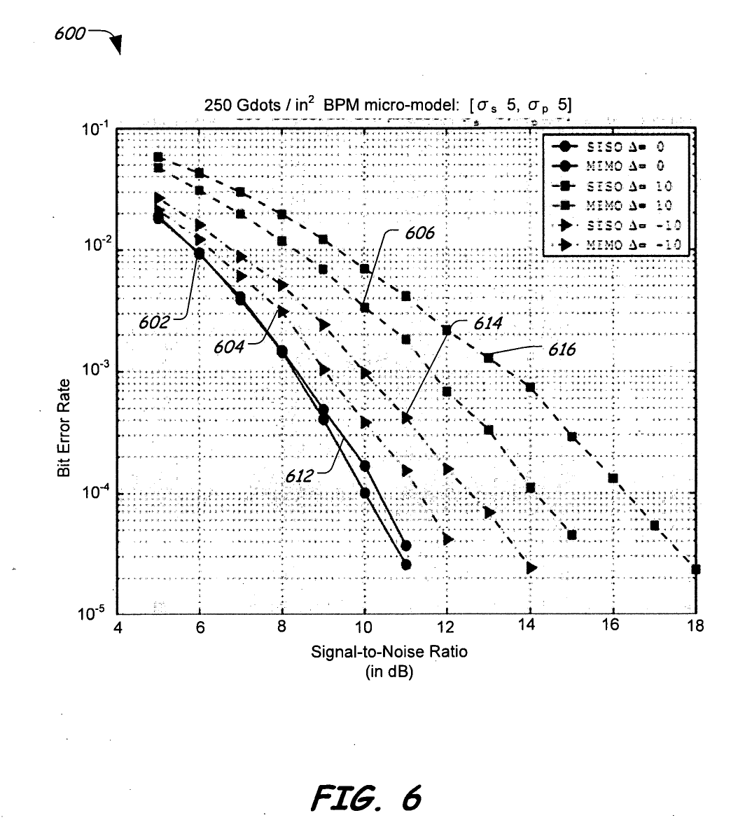

FIG. 6 is a graph 600 of BER versus SNRs for the illustrative embodiments of the SISO and MIMO Viterbi-based read-channel architectures of FIG. 5 with pattern-dependent noise at 5% size. In the graph 600, pattern-dependence in noise at five (5) percent size and position jitter are not significant. Hence, MIMO and SISO Viterbi detectors are used.

As shown, the graph 600 includes a line 602 that represents BER versus SNR for a MIMO detector with an on-track read head (i.e., the read head position delta (A) is zero). The graph 600 further includes lines 604 and 606 that represent BER versus SNR for a MIMO detector where the read head is off-track by minus or plus ten percent (10%), respectively (i.e., the read head position delta is +10 or −10). The graph also includes lines 612, 614, and 616 representing a SISO detector with a read head that is on track (A=0) and off-track by minus or plus 10% (A=+10%), respectively.

In a particular example, for the SISO and MIMO detectors where the read head is on-track (i.e., at A=0), the dot responses (or BER versus SNR responses) are similar, and (as shown at 602 and 612) hence the MIMO detector does not produce an observable SNR gain. However, when the read head deviates from the track by ten percent (as indicated at 606), the MIMO detector produces a gain of about two (2) dB. When the read head deviates from the track by minus ten percent (as indicated at 604), the MIMO detector gain is approximately one (1) dB. The gains observed from the MIMO detector can be attributed to the MIMO equalizer and target design.

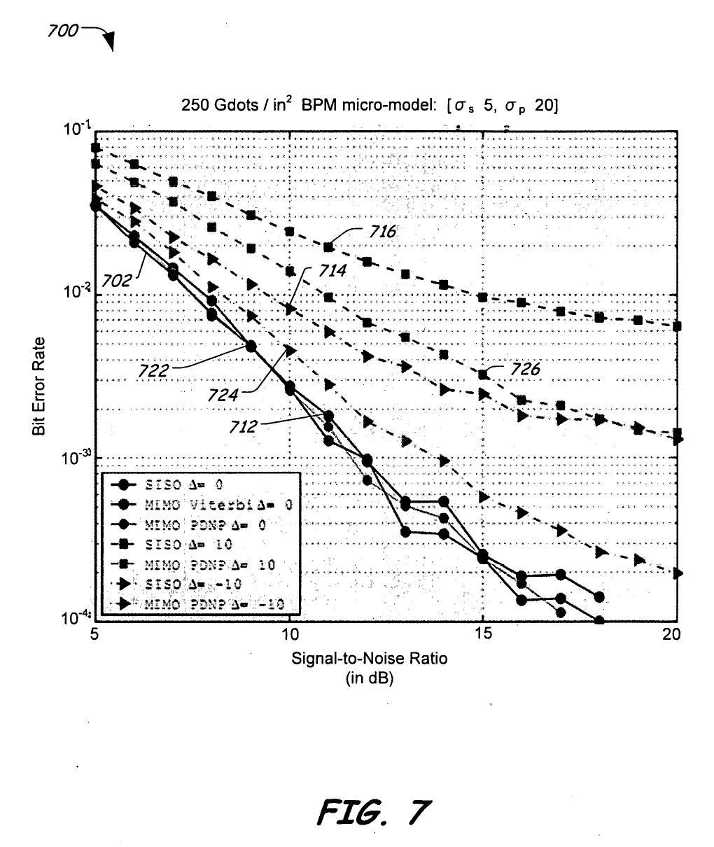

FIG. 7 is a graph 700 of BERs versus SNRs for particular embodiments of a SISO Viterbi-based detector, a MIMO Viterbi-based detector, and a MIMO data-dependent noise-prediction detector. The graph 700 includes a line 702 that represents BER versus SNR for a MIMO Viterbi-based detector with an on-track read head (i.e., the read head position delta (A) is zero). The graph also includes lines 712, 714, and 716 representing a SISO detector with a read head that is on-track (A=0) and off-track by minus or plus 10% (A=+10%), respectively. The graph further includes a line 722 that represents BER versus SNR for a MIMO data dependent noise predictive (DDNP) detector with an on-track head. The lines 724 and 726 represent the BER versus SNR for the MIMO DDNP detector with off-track head position of minus and plus 10%, respectively.

In this particular example, a significant flattening of the curve is observed due to twenty-percent position jitter. However, the MIMO DDNP detector demonstrated significant SNR gains with respect to the off-track positions (represented by lines 724 and 726). In a particular embodiment, the MIMO DDNP detector produced a gain of about 8 dB relative to the SISO detector at a read head off track positions of minus and plus 10%. Thus, the MIMO DDNP detector exhibits significant gains over SISO read-channel architectures, which gains can be observed in perpendicular recording systems, bit-patterned media-based storage systems, other data storage systems, or any combination thereof.

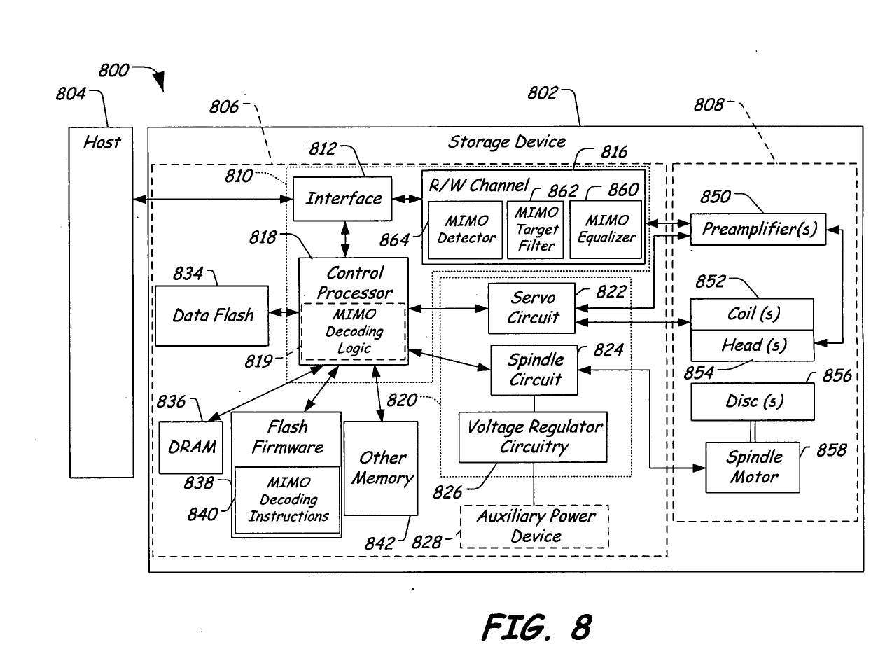

FIG. 8 is a block diagram of a particular illustrative embodiment of a system 800 including a hybrid storage device 802 having a read/write channel 816 that includes a multiple-input multiple-output (MIMO) equalizer 860, a MIMO target filter 862, and a MIMO detector 864. As used herein, the term “hybrid storage device” refers to a storage device that includes a first storage media and a second storage media. In a particular embodiment, the term “hybrid storage device” may refer to a storage device that includes both solid-state and disc storage media. Further, as used herein, the term “solid-state storage medium” refers to storage medium that utilizes semiconductor properties to represent data values and that has no moving parts to record or retrieve the data.

The hybrid storage device 802 includes both disc storage media (one or more discs 856) and solid-state storage medium, such as a flash memory device (data flash 834, flash firmware 838, etc.). The hybrid storage device 802 is adapted to communicate with a host system 804. In a particular embodiment, the host system 804 can be a computer, a processor, a mobile telephone, a personal digital assistant (PDA), another electronic device, or any combination thereof. In a particular example, the hybrid storage device 802 can communicate with the host system 804 via a universal serial bus (USB), a serial advanced technology attachment (SATA) interface, another type of communication interface, or any combination thereof. In another particular example, the hybrid storage device 802 can be a stand-alone device that is adapted to communicate with the host system 804 via a network, such as via a network cable using a networking protocol.

The hybrid storage device 802 includes recording subsystem circuitry 806 and a head-disc assembly 808. The recording subsystem circuitry 806 includes storage device read/write control circuitry 810 and disc-head assembly control circuitry 820. The recording subsystem circuitry 806 further includes an interface circuit 812, which includes a data buffer for temporarily buffering data received via the interface circuit 812 and which includes a sequencer for directing the operation of the read/write channel 816 and the preamplifier 850 during data transfer operations. The interface circuit 812 is coupled to the host system 804 and to a control processor 818, which is adapted to control operation of the hybrid storage device 802.

In a particular embodiment, the control processor 818 is adapted to execute MIMO decoding logic 819 to optionally control decoding of the read back signal from a recording medium, such as one or more discs 856. The control processor 818 is coupled to a servo circuit 822 that is adapted to control the position of one or more read/write heads 854 relative to the one or more discs 856 as part of a servo loop established by the one or more read/write heads 854. The one or more read/write heads 854 can be mounted to a rotary actuator assembly to which a coil 852 of a voice coil motor (VCM) is attached. The VCM includes a pair of magnetic flux paths between which the coil 852 is disposed so that the passage of current through the coil 852 causes magnetic interaction between the coil 852 and the magnetic flux paths, resulting in the controlled rotation of the actuator assembly and the movement of the one or more heads 854 relative to the surfaces of the one or more discs 856. In a particular embodiment, the one or more discs 856 represent rotatable, non-volatile storage media. The servo circuit 822 is used to control the application of current to the coil 852, and hence the position of the heads 854 with respect to the tracks of the one or more discs 856.

The disc-head assembly control circuitry 820 includes the servo circuit 822 and includes a spindle circuit 824 that is coupled to a spindle motor 858 to control the rotation of the one or more discs 856. The hybrid storage device 802 also includes an auxiliary power device 828 that is coupled to voltage regulator circuitry 826 of the disc-head assembly control circuitry 820 and that is adapted to operate as a power source when power to the hybrid storage device 802 is lost. In a particular embodiment, the auxiliary power device 828 can be a capacitor or a battery that is adapted to supply power to the hybrid storage device 802 under certain operating conditions, such as unexpected power loss, disconnection of alternating-current (AC) power, and other power loss events. In a particular example, the auxiliary power device 828 can provide a power supply to the recording subsystem assembly 806 and to the disc-head assembly 808 to record data to the one or more discs 856 when power is turned off. Further, the auxiliary power device 828 may supply power to the recording subsystem assembly 806 to record data to the data flash 834 when power is turned off.

Additionally, the hybrid storage device 802 includes the data flash memory 834, a dynamic random access memory (DRAM) 836, firmware 838 (i.e., a solid-state memory, such as a flash memory), other memory 842, or any combination thereof. In a particular embodiment, the firmware 838 is accessible to the control processor 818 and is adapted to store MIMO decoding logic instructions 840, which can be executed by the control processor 818.

In a particular embodiment, the read write channel 816 includes the MIMO equalizer 860, which is adapted to receive multiple inputs (such as a 1×2 bit stream) from the read/write head 854 via the preamplifier 850. In a particular embodiment, the read/write channel 816, the head 854, or the preamplifier circuit 850 can include a buffer and a formatter (such as the buffer and formatter 306) to temporarily buffer read back data and to convert the read back data into a 1×2 output bit stream that is provided to the MIMO equalizer 860. The MIMO equalizer 860 is adapted to compensate for distortion due to signal attenuation, amplification from the preamplifier, noise, other sources of distortion, or any combination thereof. The MIMO equalizer 860 produces an equalized output that is provided to the MIMO detector 864, which is adapted to make hard bit decisions based on the equalized output. The MIMO detector 864 may be coupled to a generalized partial response (GPR) MIMO target filter 862, which is adapted to generate a target response from which the equalized output to produce a difference value, which can be used by a timing error detector to produce a timing adjustment signal.

In a particular embodiment, the MIMO detector 864 is a MIMO data-dependent noise predictive (DDNP) decoder. In another particular embodiment, the MIMO equalizer 860, the MIMO target filter 862, and the MIMO decoder 864 can be programmed by the control processor 818 using the MIMO decoding logic 819.

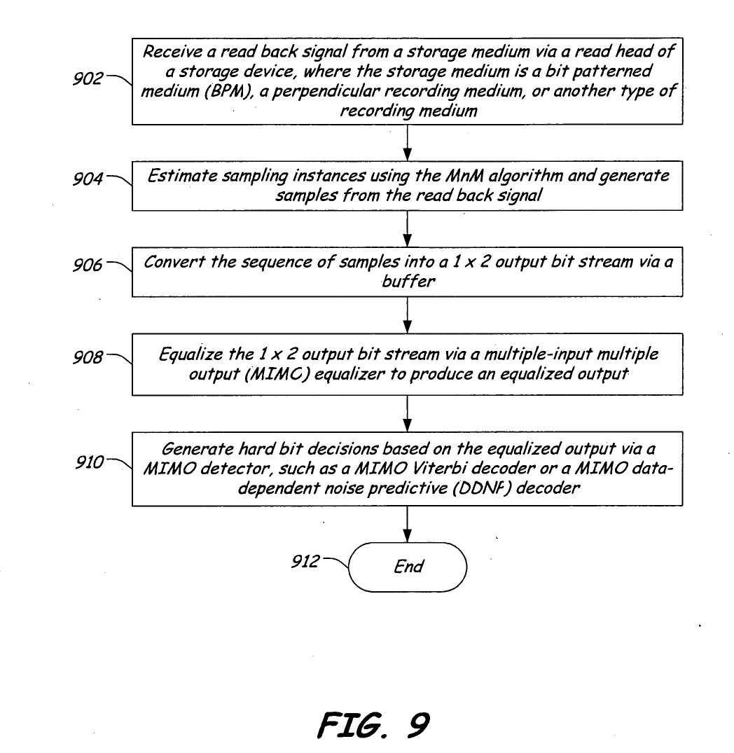

FIG. 9 is a flow diagram of a particular illustrative embodiment of a method of determining a read-back signal using a MIMO detector. At 902, a read back signal is received from a storage medium via a read head of a storage device, where the storage medium is a bit patterned medium (BPM), a perpendicular recording medium, or another type of recording medium. Advancing to 904, sampling instances are estimated using the Mueller-Muller (MnM) algorithm to generate samples from the read back signal. Proceeding to 906, the sequence of samples is converted into a 1×2 output bit stream via a buffer. In a particular embodiment, the buffer can include a formatter to convert a serial bit stream into the 1×2 output bit stream.

Continuing to 908, the 1×2 output bit stream is equalized via a multiple-input multiple-output (MIMO) equalizer to produce an equalized output. In a particular embodiment, the equalizer is adapted to compensate for distortion due to signal attenuation, amplifier-related distortion, other distortion, or any combination thereof. Proceeding to 910, hard bit decisions are generated based on the equalized output via a MIMO detector, such as a MIMO Viterbi-based decoder, a MIMO data-dependent noise-predictive (DDNP) decoder, or another MIMO decoder. In a particular embodiment where adequate training information is available, a MIMO DDNP decoder may be used to decode the data to produce a decoded output signal that has a bit error rate that is a significant improvement over a conventional SISO detector. The method terminates at 912.

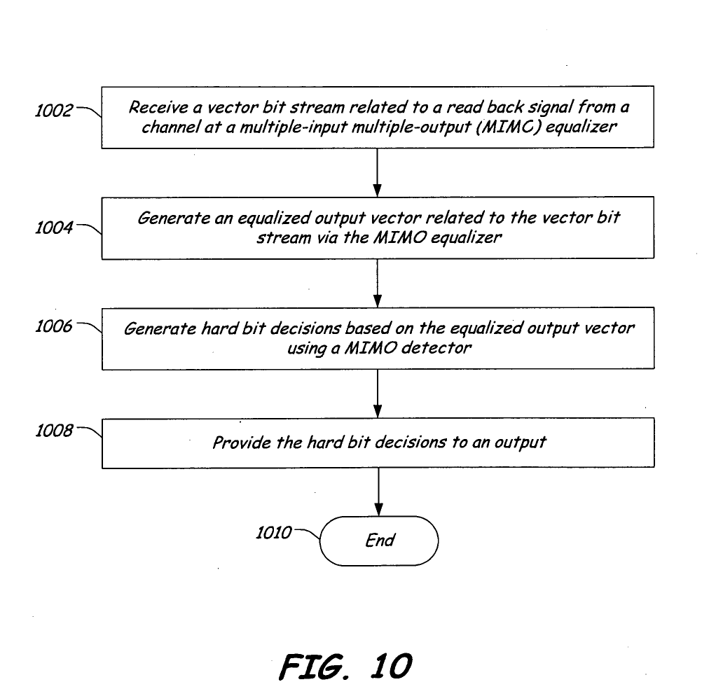

FIG. 10 is a flow diagram of a second particular illustrative embodiment of a method of determining a read-back signal using a MIMO detector. At 1002, a vector bit stream is received that is related to a read back signal from a channel at a multiple-input multiple-output (MIMO) equalizer. In a particular embodiment, the channel includes a recording channel associated with a data storage medium, such as a bit patterned medium, a perpendicular recording medium, another recording medium, or any combination thereof. Additionally, in a particular embodiment, the vector bit stream includes a 1×2 vector bit stream, which may be produced by a buffer/formatter that is adapted to receive a serial bit stream (read back signal) and to produce a vector output related to the read back signal.

Advancing to 1004, an equalized output vector is generated that is related to the vector bit stream via the MIMO equalizer. Proceeding to 1006, hard bit decisions are generated based on the equalized output vector using a MIMO detector. Continuing to 1008, the hard bit decisions are provided to an output. The method terminates at 1010.

In a particular embodiment, the method further includes determining a target vector related to the hard bit decisions at a generalized partial response (GPR) MIMO target filter and calculating a timing error vector based on a difference between the equalized output vector and the target vector via a timing error detector. The method further includes feeding back the timing error vector via a loop filter. In a particular example, the timing error detector comprises a Mueller-Müller (M&M) Timing error detector. In another particular embodiment, the method further includes interpolating the vector bit stream via an interpolator based on the timing error vector and providing the interpolated vector bit stream to the MIMO equalizer as the vector bit stream.

It is to be understood that even though numerous characteristics and advantages of various embodiments of the invention have been set forth in the foregoing description, together with details of the structure and function of various embodiments of the invention, this disclosure is illustrative only, and changes may be made in detail, especially in matters of structure and arrangement of parts within the principles of the present invention to the full extent indicated by the broad general meaning of the terms in which the appended claims are expressed. For example, the particular elements may vary depending on the particular application for the data storage system while maintaining substantially the same functionality without departing from the scope and spirit of the present invention. In addition, although the preferred embodiment described herein is directed to a data storage system having a MIMO equalizer, a MIMO target filter, and a MIMO detector for decoding user data from a read back signal, it will be appreciated by those skilled in the art that the teachings of the present invention can be applied to other communication channels that are sampled serially, that provide multiple input data, that include data-dependent noise, or any combination thereof, without departing from the scope and spirit of the present invention.

What is claimed is:

1. A storage device comprising:
a data storage medium; and
a read/write circuit coupled the data storage medium via a communication channel,
the read/write circuit comprising:
a formatter circuit to receive a read back signal related to data stored on the data storage medium and to produce an output vector related to the read back signal;
a multiple-input multiple-output (MIMO) equalizer coupled to the formatter circuit and adapted to generate an equalized output vector related to the output vector; and
a MIMO detector coupled to the MIMO equalizer and adapted to generate hard bit decisions based on the equalized output vector.

2. The storage device of claim 1, further comprising a MIMO target filter coupled to the MIMO detector and adapted to generate a target vector related to the hard bit decisions.

3. The storage device of claim 2, further comprising a timing error detector coupled to the MIMO target filter and adapted to generate a timing error vector based on a difference between the target vector and the equalized output vector.

4. The storage device of claim 3, wherein the data storage medium comprises a bit patterned medium (BPM), and wherein the output vector is related to user symbols associated with first and second sub-tracks of the BPM.

5. The storage device of claim 3, wherein the data storage medium comprises a perpendicular recording medium, and wherein the output vector is related to user symbols associated with adjacent tracks of the perpendicular recording medium.

6. The storage device of claim 3, wherein the MIMO detector comprises a MIMO data-dependent noise predictive (DDNP) decoder.

7. A system comprising:
a multiple-input multiple-output (MIMO) equalizer adapted to receive an input vector related to a read-back signal from a data storage medium to produce an equalized output vector; and
a MIMO detector adapted to decode the equalized output vector to generate hard bit decisions and to provide the hard bit decisions to an output.

8. The system of claim 7, wherein the MIMO detector comprises a MIMO data-dependent noise predictive decoder.

9. The system of claim 7, wherein the MIMO detector comprises a MIMO Viterbi-based decoder.

10. The system of claim 7, further comprising:
a MIMO target filter to produce a target vector based on the hard bit decisions; and
a timing error detector to determine a timing error vector related to a difference between the equalized output vector and the target vector.

11. The system of claim 10, further comprising:
a loop filter to receive the timing error vector and to produce a feedback timing vector; and
an interpolator coupled to the loop filter and to a buffer to receive an input bit stream related to the read back signal and to produce the input vector based on the input bit stream and the feedback timing vector.

12. The system of claim 11, wherein the timing error detector is adapted to produce two timing updates via the timing error vector every two time intervals.

13. The system of claim 7, wherein the data storage medium comprises a bit patterned medium, and wherein the read back signal is related to first and a second sub-tracks of the bit patterned data storage media,

14. The storage device of claim 7, wherein the data storage medium comprises a perpendicular recording medium, and wherein the output vector is related to user symbols associated with adjacent tracks of the perpendicular recording medium.

15. A method comprising:
receiving a vector bit stream related to a read back signal from a channel at a multiple-input multiple-output (MIMO) equalizer;
generating an equalized output vector related to the vector bit stream via the MIMO equalizer;
generating hard bit decisions based on the equalized output vector using a MIMO detector; and
providing the hard bit decisions to an output.

16. The method of claim 15, wherein the channel comprises a recording channel associated with a data storage medium.

17. The method of claim 15, wherein the vector bit stream comprises a 1×2 vector bit stream.

18. The method of claim 15, further comprising:
determining a target vector related to the hard bit decisions at a generalized partial response (GPR) MIMO target filter;
calculating a timing error vector based on a difference between the equalized output vector and the target vector via a timing error detector; and
feeding back the timing error vector via a loop filter.

19. The method of claim 18, wherein the timing error detector comprises a Mueller-Müller (M&M) Timing error detector.

20. The method of claim 17, further comprising:
interpolating the vector bit stream via an interpolator based on the timing error vector; and
providing the interpolated vector bit stream to the MIMO equalizer as the vector bit stream.
